(19) United States
(12) Patent Application Publication
(10) Pub. No.: US 2020/0403012 A1
(43) Pub. Date: Dec. 24, 2020

(54) DISPLAY PANEL AND MANUFACTURING METHOD THEREOF

(71) Applicant: WUHAN CHINA STAR OPTOELECTRONICS TECHNOLOGY CO., LTD., Wuhan, Hubei (CN)

(72) Inventors: Rong MA, Wuhan, Hubei (CN); Guanghui LIU, Wuhan, Hubei (CN)

(21) Appl. No.: 16/609,211

(22) PCT Filed: Aug. 14, 2019
(86) PCT No.: PCT/CN2019/100627

§ 371 Date: Oct. 29, 2019

(30) Foreign Application Priority Data
Jun. 24, 2019 (CN) 201910547111.7

(51) Int. Cl. H01L 27/12; H01L 33/58

(52) U.S. Cl. CPC H01L 27/1262; H01L 33/58; H01L 27/124; H01L 27/1218

(57) ABSTRACT

The present invention provides a display panel and a manufacturing method thereof. The display panel comprises an array substrate provided with a first inclined plane at an edge of one side of the array substrate; a color filter substrate disposed on one side surface of the array substrate; the color filter substrate provided with a second inclined plane at an edge of one side of the color filter substrate, and the second inclined plane on a same plane with the first inclined plane; and a chip on film bonded to the first inclined plane and the second inclined plane. A manufacturing method of the display panel comprises an array substrate providing step, a color filter substrate disposing step, a cutting step and a bonding step. The technical effect of the present invention is reducing the thickness of the bottom frame of the display panel and increasing the screen ratio.

### FIELD OF INVENTION

The present invention relates to a display, and more specifically, to a display panel and a manufacturing method thereof.

### BACKGROUND OF INVENTION

Recently, low temperature poly-silicon (LTPS) display panels are getting into more and more applications in mid to high-end small size products. LTPS display panels have advantages of high resolution, high aperture ratio, high response speed, and low power consumption, and currently a lot of new techniques are developed to increase the screen ratio of the panel, such as having a narrow border, chip on film (COF) and profile display. These known techniques currently have their own limitations:

The narrow border mainly compresses the left and right borders by cut on seal.

A chip on film (COF) is integrated on a flexible printed circuit board (FPC), and COF is bonded to the TFT glass by an anisotropic conductive film (ACF).

The profile display avoids only the camera area by upper edge profile-cutting to increase display area.

As shown in FIG. 1, the current display panel comprises an array substrate 100, a color filter substrate 200 and a chip on film 300. The color filter substrate 200 is disposed on an upper surface of the array substrate 100, the chip on film 300 is bonded to an upper surface of one end of the array substrate 100 and bending to a back side of the array substrate 100, and the integrated circuit unit is disposed on an upper surface of the chip on film 300 which bending to a back side of the array substrate 100. This decreases the bonding area of the integrated circuits, but it needs to reserve space for attachment of an anisotropic conductive film, thereby greatly reducing the screen ratio of the display panel.

When the display panel shown in FIG. 1 is mounted to a display device (such as a smartphone), the chip on film 300 on the right side of the figure is installed in the frame on one side of the display device. To release the stress of the chip on film 300, the chip on film 300 needs to occupy a predetermined space to ensure it have a radian. Therefore, the frame installed with the chip on film 300 needs a predetermined width. The frame installed with the chip on film 300 is generally disposed as a bottom frame of the display device in prior art.

The object of the present invention is to solve a large width of the bottom frame and a low screen ratio of the display device.

### SUMMARY OF INVENTION

To achieve above objects, the present invention provides a display panel, comprising: an array substrate provided with a first inclined plane at an edge of one side of the array substrate;

a color filter substrate disposed on one surface of the array substrate; the color filter substrate provided with a second inclined plane at an edge of one side of the color filter substrate, and the second inclined plane on a same plane with the first inclined plane; and a chip on film bonded to the first inclined plane and the second inclined plane.

Further, the display panel further comprises a silver wire layer attached to the first inclined plane and the second inclined plane; and a conductive adhesive layer attached to a surface of the silver wire layer, wherein the chip on film is bonded to the conductive adhesive layer.

Further, the silver wire layer comprises two or more parallel wires, one end of any of the wires is electrically connected to the array substrate and another end is electrically connected to the chip on film.

Further, one side of the array substrate opposite to the first inclined plane is a first side plane; one side of the color filter substrate opposite to the second inclined plane is a second side plane; and the first side plane and the second side plane are on a same plane.

Further, the chip on film is integratedly formed with

a first film bonded to an outer surface of the conductive adhesive layer;

a second film disposed opposite to the array substrate; and

a bending portion with one end connected to the first film and another end connected to the second film.

Further, the chip on film further comprises a circuit unit attached to one surface of the second film adjacent to the array substrate.

To achieve above objects, the present invention further provides a manufacturing method of a display panel, comprising following steps:

an array substrate providing step: providing an array substrate;

a color filter substrate disposing step: disposing a color filter substrate on an upper surface of the array substrate;

a cutting step: cutting one side of the color filter substrate and the array substrate to form a first inclined plane on one side of the array substrate and a second inclined plane on one side of the color filter substrate, and the second inclined plane on a same plane with the first inclined plane; and a bonding step: bonding a chip on film to the first inclined plane and the second inclined plane.

Further, in the color filter substrate disposing step, a side plane of the color filter substrate is on a same plane with a side plane of the array substrate.

Further, after the cutting step, the manufacturing method of the display panel further comprises: a silver paste coating step: spray coating a layer of silver paste to form a silver paste layer on the first inclined plane and the second inclined plane;

an etching step: laser etching the silver paste layer, and etching two or more parallel wires to form a silver wire layer; and a conductive adhesive layer attaching step: attaching a conductive adhesive layer on an outer surface of the silver wire layer.

Further, in the bonding step, a first film is bonded to a surface of the conductive adhesive layer, a second film is disposed under the array substrate, and one end of a bending portion is connected to the first film and another end is connected to the second film.

The technical effect of the present invention is making one end of the array substrate and the color filter substrate as inclined planes, bonding the chip on film to the inclined planes, and disposing the chip on film integrally on a side of the array substrate facing away from the display area at the same time. When the display panel is mounted to a display device (such as a smartphone), the chip on film is installed in the case not in the frame. Therefore, the width of the frame of the display device can be designed smaller to further increase the screen ratio of the display device and improve market competitiveness.

### DESCRIPTION OF DRAWINGS

FIG. 1 is a schematic structural diagram of a display panel in prior art.

FIG. 2 is a flow chart of a manufacturing method of the display panel according to one embodiment in the present invention.

FIG. 3 is a schematic structural diagram of a display panel after the cutting step according to one embodiment in the present invention.

FIG. 4 is a schematic diagram of the silver wire layer according to one embodiment in the present invention.

FIG. 5 is a schematic structural diagram of the display panel according to one embodiment in the present invention.

### DETAILED DESCRIPTION OF PREFERRED EMBODIMENTS

The embodiments of the present disclosure are described in detail hereinafter. Examples of the described embodiments are given in the accompanying drawings. The specific embodiments described with reference to the attached drawings are all exemplary and are intended to illustrate and interpret the present disclosure, which shall not be construed as causing limitations to the present disclosure.

In the description of the present disclosure, it should be understood that terms such as “upper,” “lower,” “front,” “rear,” “left,” “right,” “inside,” “outside,” “side” as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure.

In the accompanying drawings, the identical or similar reference numerals constantly denote the identical or similar elements or elements having the identical or similar functions. Besides, the dimensions and thickness of each component shown in the accompanying drawings are arbitrarily shown for ease of understanding and description, and are not limited by the present invention.

In the description of the present disclosure, unless specified or limited otherwise, it should be noted that, a structure in which a first feature is “on” a second feature may include an embodiment in which the first feature directly contacts the second feature and may also include an embodiment in which an additional feature is formed between the first feature and the second feature so that the first feature does not directly contact the second feature. The terms such as “mount,” “connect,” and “bond” should be comprehended in broad sense. For example, it can mean a direct connection, or an indirect connection by an intermediate.

As shown in FIG. 2, the present invention provides a manufacturing method of a display panel, comprising following S1 to S7.

S1: an array substrate providing step: providing an array substrate, the array substrate is provided with a first side plane, and the thickness of the array substrate ranges from 0.1 mm to 0.2 mm, preferably 0.15 mm in the embodiment. The array substrate provides circuit support for the display panel.

S2: a color filter substrate disposing step: disposing a color filter substrate on an upper surface of the array substrate. Disposing a color filter substrate on an upper surface of the array substrate by an adhesive layer, and making side planes of the color filter substrate and the array substrate are on a same plane, wherein the color filter substrate is provided with a second side plane, and the second side plane and the first side plane are on the same plane. The thickness of the color filter substrate ranges from 0.1 mm to 0.2 mm, preferably 0.15 mm in the embodiment. The color filter substrate is used to filter and makes the display panel display color.

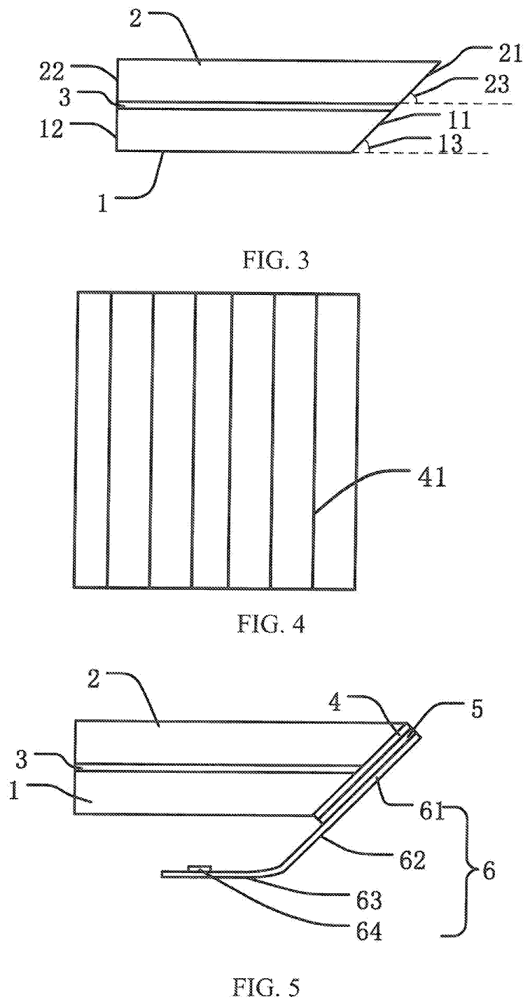

S3: a cutting step: using laser to cut the array substrate and the color filter substrate. The cut surface formed from the cutting process with an upper or lower surface of the array substrate or the color filter substrate forms a cutting angle, the cutting angle ranges from 30° to 60°. The structure of the display panel after the cutting step is as shown in FIG. 3. Cutting from the edge of the color filter substrate as shown in FIG. 3 to the lower left to form a first inclined plane on one side of the array substrate, and form a second inclined plane on one side of the color filter substrate. The first inclined plane and the second inclined plane are on the same plane, the angle between the first inclined plane and the horizontal plane is a first tilt angle, and the angle between the second inclined plane and the horizontal plane is a second tilt angle. The first tilt angle ranges from 30° to 60°, The second tilt angle ranges from 30° to 60°, so in different embodiments, the first tilt angle can be 35°, 40°, 45°, 50°, or 55°, etc., and the second tilt angle can be 35°, 40°, 45°, 50°, or 55°, etc.; It is not limited to the embodiment.

When the first tilt angle or the second tilt angle is a smaller angle (such as 30°, 35°, 40°, etc.), the area of the first inclined plane and the second inclined plane to be used is larger, so the coating area for the subsequent silver paste and anisotropic conductive film is larger, too. It can improve adhesion for the silver paste and the anisotropic conductive film, and the area for the bonded chip on film is larger, too. When the first tilt angle or the second tilt angle is a larger angle (such as 45°, 50°, 55°, 60°, etc.), the area of the first inclined plane and the second inclined plane to be used is smaller, so the coating area for the subsequent silver paste and anisotropic conductive film is smaller and the area for the bonded chip on film is smaller, too. Therefore, the tilt angle can be determined according to the area needed for the chip on film to bonding.

Due to the total thickness of the array substrate and the color filter substrate ranging from about 0.2 mm to 0.5 mm, being a smaller thickness, it is difficult for coating on a side plane of the array substrate and the color filter substrate. Therefore, through the cutting step in the embodiment, form a first inclined plane and a second inclined plane on a side of the array substrate and the color filter substrate to increase the area to be used for subsequent processes, that is enlarging the coating area for the subsequent silver paste and anisotropic conductive film to improve the adhesion for the silver paste and the anisotropic conductive film.

S4: a silver paste coating step: spray coating a layer of silver paste to form a silver paste layer on the first inclined plane and the second inclined plane. The silver paste has conductive parts and can be used as a conductive material. In the embodiment, the silver paste layer is used for conduction.

S5: an etching step: laser etching the silver paste layer, and etching two or more parallel wires to form a silver wire layer (as shown in FIG. 4). One end of any of the wires is electrically connected to the array substrate and another end is electrically connected to the subsequent chip on film, to conduct the circuit between the chip on film and the array substrate.

S6: a conductive adhesive layer attaching step: attaching an anisotropic conductive film (ACF) on an outer surface of the silver wire layer to form a conductive adhesive layer. The anisotropic conductive film has good electrical conductivity. The conduction principle of the anisotropic conductive film is using conductive particles to connect the electrodes between the integrated circuit chip and the array substrate to conduction and to avoid short circuit between two adjacent electrodes, thereby achieving the object of conduction in the z-axis direction. Materials of the anisotropic conductive film comprise resin adhesives and conductive particles. The resin adhesives have moisture-proof, heat-resistant and insulating properties, and mainly maintain the relative positions between electrodes of the integrated circuit chip and the array substrate, and provide a compressive force to maintain the contact area between the electrodes and the conductive particles.

S7: a bonding step: bonding a chip on film to an outer surface of the conductive adhesive layer. the chip on film is integratedly formed with a first film, a bending portion, and a second film. The first film is bonded to a surface of the conductive adhesive layer, the second film is disposed under the array substrate, and one end of the bending portion is connected to the first film and another end is connected to the second film. The angle between the second film and the first film ranges from 120° to 150°, that is, the bending angle of the bending portion ranges from 120° to 150°, making better attachment between the chip on film and the conductive adhesive layer and ensuring good conduction between the chip on film and the conductive adhesive layer. An upper surface of the second film is provided with a circuit unit, and the circuit unit is electrically connected to the array substrate through the chip on film, the conductive adhesive layer and the silver wire layer to form conduction of electrical signals of the display panel.

After the bonding step, the manufacturing method of the display panel of the present invention further comprises a polarizer manufacturing step, a backlight module manufacturing step and relative processes to manufacture a qualified display panel.

The manufacturing method of the display panel in the embodiment comprises making one end of the array substrate and the color filter substrate as inclined planes, bonding the chip on film to the inclined planes, and disposing the chip on film integrally on a side of the array substrate facing away from the display area at the same time. When the display panel is mounted to a display device (such as a smartphone), the chip on film is installed in the case not in the frame. Therefore, the width of the frame of the display device can be designed smaller to further increase the screen ratio of the display device and improve market competitiveness.

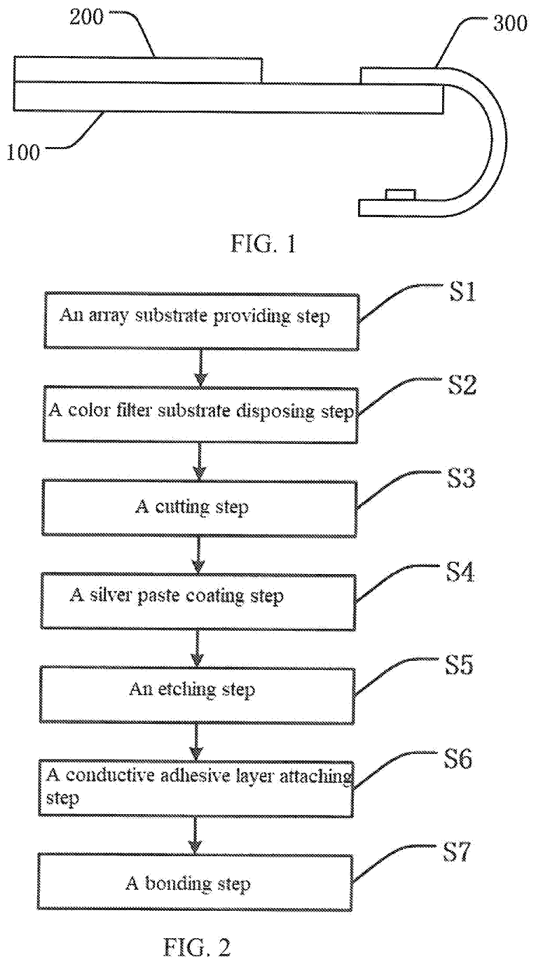

Comparative to the display panel as shown in FIG. 1, there's no need to reserve coating space for the anisotropic conductive film in the frame area of the display device, reducing the thickness of the frame of the display device and increasing the screen ratio of the display device, thereby improving market competitiveness in display devices.

As shown in FIG. 5, the embodiment further provides a display panel prepared by the above manufacturing method. The display panel comprises an array substrate 1, a color filter substrate 2, an adhesive layer 3, a silver wire layer 4, a conductive adhesive layer 5 and a chip on film 6.

The array substrate 1 provides circuit support for the display panel, and the thickness of the array substrate 1 ranges from 0.1 mm to 0.2 mm, preferably 0.15 mm in the embodiment. The array substrate 1 comprises a first inclined plane 11 and a first side plane 12 (as shown in FIG. 3), and the angle between the first inclined plane 11 and the horizontal plane is a first tilt angle 13; the first tilt angle 13 ranges from 30° to 60°; the first tilt angle 13 can be 35, 40°, 45°, 50°, 55°, etc. in different embodiments, and is not limited in the embodiment. The first inclined plane 11 and the first tilt angle 13 increase the area to be used for the subsequent processes.

The color filter substrate 2 is disposed on an upper surface of the array substrate 1 to filter and makes the display panel display color. The thickness of the color filter substrate 2 ranges from 0.1 mm to 0.2 mm, preferably 0.15 mm in the embodiment. A side plane of the color filter substrate 2 is on a same plane with a side plane of the array substrate 1; the color filter substrate 2 comprises a second inclined plane 21 and a second side plane 22; the second inclined plane 21 and the first inclined plane 11 are on a same plane, and the second side plane 22 and the first side plane 12 are on a same plane (as shown in FIG. 3). The angle between the second inclined plane 21 and the horizontal plane is a second tilt angle 23; the second tilt angle 23 ranges from 30° to 60°; the first tilt angle 13 can be 35°, 40, 45, 50°, 55°, etc. in different embodiments, and is not limited in the embodiment. The second inclined plane 21 and the second tilt angle 23 increase the area to be used for the subsequent processes.

The adhesive layer 3 is disposed between the array substrate 1 and the color filter substrate 2 to bond the array substrate 1 and the color filter substrate 2.

The silver wire layer 4 is attached to the first inclined plane 11 and the second inclined plane 21 to conduction. The silver wire layer 4 comprises two or more parallel wires 41, one end of any of the wires 41 is electrically connected to the array substrate 1 and another end is electrically connected to the chip on film 6.

The conductive adhesive layer 5 is attached to an outer surface of the silver wire layer 4 to conduction. The material of the conductive adhesive layer 5 is an anisotropic conductive film (ACF), having a good electrical conductivity. The conduction principle of the anisotropic conductive film is using conductive particles to connect the electrodes between the integrated circuit chip and the array substrate to conduction and to avoid short circuit between two adjacent electrodes, thereby achieving the object of conduction in the z-axis direction. Materials of the anisotropic conductive film comprise resin adhesives and conductive particles. The resin adhesives have moisture-proof, heat-resistant and insulating properties, and mainly maintain the relative positions between electrodes of the integrated circuit chip and the array substrate and provide a compressive force to maintain the contact area between the electrodes and the conductive particles.

The chip on film 6 is bonded to the conductive adhesive layer 5 to provide circuit support. The chip on film 6 is integratedly formed with a first film 61, a bending portion 62, and a second film 63. The first film 61 is bonded to an outer surface of the conductive adhesive layer 5, the second film 63 is disposed under the array substrate 1 and opposite to the array substrate 1, and one end of the bending portion 62 is connected to the first film 61 and another end is connected to the second film 63. The angle between the second film 63 and the first film 61 ranges from 120° to 150°, that is, the bending angle of the bending portion 62 ranges from 120° to 150°, making better attachment between the chip on film 6 and the conductive adhesive layer 5 and ensuring good conduction between the chip on film 6 and the conductive adhesive layer 5. An upper surface of the second film 63 is provided with a circuit unit 64, and the circuit unit 64 is electrically connected to the array substrate 1 through the chip on film 6, the conductive adhesive layer 5 and the silver wire layer 4 to form conduction of electrical signals of the display panel.

Compared to the display panel in FIG. 1, which is using bending to bond the chip on film, although reducing the thickness of the bottom frame to a certain extent, it still needs to reserve the coating space for the anisotropic conductive film. The display panel in the embodiment, which has a cut first inclined plane on one side of the array substrate and a cut second inclined plane on one side of the color filter substrate, the chip on film is directly bonded to the first inclined plane and the second inclined plane; since the cutting direction is cut inward from the edge, the bonded chip on film is also bent inward, thereby greatly reducing the thickness of the bottom frame of the display panel, improving the utilization of the display panel and improving the screen ratio of the display panel.

The display panel in the embodiment comprises making one end of the array substrate and the color filter substrate as inclined planes, bonding the chip on film to the inclined planes, and disposing the chip on film integrally on one side of the array substrate facing away from the display area at the same time. When the display panel is mounted to a display device (such as a smartphone), the chip on film is installed in the case not in the frame. Therefore, the width of the frame of the display device can be designed smaller to further increase the screen ratio of the display device and improve market competitiveness in display devices.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A display panel, comprising:
an array substrate provided with a first inclined plane at an edge of one side of the array substrate;
a color filter substrate disposed on one side surface of the array substrate;
the color filter substrate provided with a second inclined plane at an edge of one side of the color filter substrate, the second inclined plane on a same plane with the first inclined plane; and
a chip on film bonded to the first inclined plane and the second inclined plane.

2. The display panel according to claim 1, comprising:
a silver wire layer attached to the first inclined plane and the second inclined plane; and
a conductive adhesive layer attached to a surface of the silver wire layer, wherein the chip on film is bonded to the conductive adhesive layer.

3. The display panel according to claim 2, wherein the silver wire layer comprises two or more parallel wires, one end of any of the wires is electrically connected to the array substrate and another end is electrically connected to the chip on film.

4. The display panel according to claim 1, wherein one side of the array substrate opposite to the first inclined plane is a first side plane; one side of the color filter substrate opposite to the second inclined plane is a second side plane; and the first side plane and the second side plane are on a same plane.

5. The display panel according to claim 1, wherein the chip on film is integratedly formed with
a first film bonded to an outer surface of the conductive adhesive layer;
a second film disposed opposite to the array substrate; and
a bending portion with one end connected to the first film and another end connected to the second film.

6. The display panel according to claim 5, wherein the chip on film further comprises a circuit unit attached to one surface of the second film adjacent to the array substrate.

7. A manufacturing method of a display panel, comprising following steps:
an array substrate providing step: providing an array substrate;
a color filter substrate disposing step: disposing a color filter substrate on an upper surface of the array substrate;
a cutting step: cutting one side of the color filter substrate and the array substrate to form a first inclined plane on one side of the array substrate and a second inclined plane on one side of the color filter substrate, and the second inclined plane on a same plane with the first inclined plane; and
a bonding step: bonding a chip on film to the first inclined plane and the second inclined plane.

8. The manufacturing method of a display panel according to claim 7, wherein in the color filter substrate disposing step, a side plane of the color filter substrate is on a same plane with a side plane of the array substrate.

9. The manufacturing method of a display panel according to claim 7, wherein after the cutting step, the method further comprises:
a silver paste coating step: spray coating a layer of silver paste to form a silver paste layer on the first inclined plane and the second inclined plane;
an etching step: laser etching the silver paste layer, and etching two or more parallel wires to form a silver wire layer; and
a conductive adhesive layer attaching step: attaching a conductive adhesive layer on an outer surface of the silver wire layer.

10. The manufacturing method of a display panel according to claim 9, wherein in the bonding step, a first film is bonded to a surface of the conductive adhesive layer, a second film is disposed under the array substrate, and one end of a bending portion is connected to the first film and another end is connected to the second film.
